(19) United States
(12) Patent Application Publication
(10) Pub. No.: US 2007/0023762 A1
(43) Pub. Date: Feb. 1, 2007

(54) White light emitting LED-powered lamp

(75) Inventors: Samuel P. Gumins, Wilton, CT (US); Julius Muschaweck, Gauting (DE)

Correspondence Address: JLB CONSULTING, INC.;c/o INTELLEVATE, P.O. BOX 52050, MINNEAPOLIS, MN, 55402, US

(73) Assignee: Luxo ASA and OEC AG

(21) Appl. No.: 11/193,843

(22) Filed: Jul. 29, 2005

(51) Int. Cl. H01L 33/00

(52) U.S. Cl. 257/79

(57) ABSTRACT

The invention relates to a white light emitting LED lamp. The LED lamp comprises an LED emitting blue light and luminescent layer for converting a part of the blue light into light having a longer wavelength. According to the invention either a dye is provided for absorbing a part of the blue light emitted by the LED or a light reflecting layer is provided for selectively reflecting a part of the blue light emitted by the LED. Thus the proportion of the blue light is reduced which results in a reduced color temperature without having a negative effect on the color rendering and only reducing the total luminous flux by a small amount, which is more efficient than using a thicker luminescent coating.

### FIELD OF THE INVENTION

The invention relates to a light-emitting device and more particularly to methods and apparatus for a white light-emitting, LED-powered lamp.

### BACKGROUNG OF THE INVENTION

There are several kinds of white light emitting diodes (LED). The type of white light LED which is mostly used comprises a blue light LED and a luminescent layer for converting a part of the blue light into light with larger wavelength.

WO 01/89001 A2 discloses white light-emitting phosphor blends for LED devices. Therein it is discussed that blue light emitted by the LED excites a luminescent material causing emission of yellow light. The blue light emitted by the LED is transmitted to the luminescent material and is mixed with the yellow light emitted by the luminescent material. The viewer perceives the mixture of blue and yellow light as white light.

However, such a white light illumination system suffers from the following disadvantages. Prior art blue LED-YAG:Ce phosphor systems produce white light with a high color temperature ranging from 6000 K to 8000 K, which is comparable to sunlight, and a typical color rendering index (CRI) of about 70 to 75. In other words, color coordinates of this system are located adjacent to the Black Body Locus (“BBL”) between the color temperatures of 6000 K and 8000 K on the Commision Internationale de L'Eclairage (CIE) chromaticity diagram illustrated in FIG. 1. The high color temperature of this system can be reduced by increasing the phosphor thickness. It was already recognized that the increased phosphor thickness decreases the system efficiency.

While the blue LED-YAG:Ce phosphor illumination system with a relatively high color temperature and a relatively low CIE is acceptable to customers in the far east lighting markets, the customers in the North American markets generally prefer an illumination system with lower color temperature, and the customers of European markets generally prefer an illumination system with a high CRI.

The chromaticity coordinates and the CIE chromaticity diagram illustrated in FIG. 1 are explained in detail in several text books, such as Gerd Goldmann, “The World of Printers” (océ printing systems GmbH, Edition 3a, November 1998, ISBN 3-00-001081-5) Chapter 8, and J. R. Coaton and A. M. Marsden, “Lamps and Lighting” (Fourth Edition, Arnold and Contributors 1997, ISBN 0 340 64618). These two documents and the WO 01/98001 A2 are incorporated herein by reference.

The chromaticity coordinates (i.e. color points) that lie along the BBL obey Planck's equation: E(λ)=Aλ⁻⁵/(e^{(B/T)}−1), where E is the emission intensity, λ is the emission wavelength, T the color temperature and A and B are constants. Color coordinates that lie on or near the BBL yield pleasing white light to a human observer.

The “color rendering index” (CRI) is established by visual experiment. The correlated color temperature of a light source to be evaluated is determined. Then eight color samples are illuminated first by the light source and then by light from a black body having the same color temperature. If a standard color sample does not change color, then the light source has a theoretically perfect special CRI of 100. A general color rendering index is termed “Ra”, which is an average of the CRIs of all eight standard color samples.

Thus CRI is a relative measurement of how the color rendition of an illumination system compares to that of a black body radiator. The CRI equals 100 if the color coordinates of a set of test colors being illuminated by the illumination system are the same as the coordinates of the same test colors being irradiated by the black body radiator.

U.S. Pat. No. 6,084,250 describes a light-emitting device comprising a UV-diode with a primary emission of 300 nm≦λ≦370 nm and a luminescent layer including a combination of blue-emitting phosphor having an emission band, with 430 nm≦λ≦490 nm, a green-emitting phosphor having an emission band with 520 nm≦λ≦570 nm and a red-emitting phosphor having an emission band with 590 nm≦λ≦630 nm, that is purported to emit high-quality white light. The color-rendering index CRI is expected be approximately 90 at a color temperature of 4000 K. This light-emitting device comprises a rather complicated blend of phosphor materials for converting the emitted UV-light into visible lights of different wavelengths. An advantage of this device is that the color temperature and the color rendition depend only on the composition of the luminescent materials not on the relation between converted and non-converted light. A disadvantage is that the use of a blend of luminescent materials, while providing a white light of high quality as the color temperature is rather low, needs a large number of different luminescent materials which causes high costs and which also reduces the luminous flux.

To overcome the above described disadvantages it is suggested in WO 01/89001 A2 to provide a white light illumination system comprising a light emitting diode and a blend of different luminescent materials.

A further white light emitting phosphor blend for LED devices is described in WO 01/89000 A1.

From WO 01/24283 A1 it is known that a light emitting diode may be created by using a plurality of thin films of luminescent materials to provide white light with high quality.

From WO 01/24229 A2 a lamp is known comprising a mixture of two luminescent materials as an excitation energy source in a light emitting diode. In particular, the lamp employs a blue LED and a mixture of red and green luminescent materials for the production of white light.

As it is shown above, the usual course to increase the quality of white light is to use a blend of luminescent materials to adjust the color temperature of the white light LED lamp. However, this increases the thickness of the luminescent layer which reduces the efficiency of the lamp. It may also increase the expense and complexity of the device.

Another approach to provide a white light emitting LED lamp is disclosed in U.S. Pat. No. 5,851,063, wherein at least three multi-colored LEDs are used, providing the disadvantages of complexity and expense.

From WO 2004/077580 A2 a composite white light source is known including a light source and a separately formed conversion material region with conversion particles. The conversion material region is positioned in proximity to the light source such that at least some of the light source light passes through the conversion material region. The conversion particles absorb some of the light source light passing through the conversion material region and emitting a second spectrum of light. The conversion material region is preferably an optical lens in which the conversion particles are uniformly distributed so that the color and the intensity of the emitted light are uniform throughout a wide range of viewing angles. The present inventors believe that the described conversion materials and structure provide less than a desirable white light.

The present inventors believe that there has yet to be provided a simple, cost-effective, efficient LED-powered white light lamp having acceptable characteristics for the international market.

### SUMMARY OF THE INVENTION

An object of the invention is to provide a white light emitting LED lamp for emitting white light with a high quality; particularly a color temperature below 4500 K.

A further object of the present invention is to provide a white light emitting LED lamp having a simple structure.

A further object of the present invention is to provide a white light emitting LED lamp which can be produced at low costs.

In accordance with one embodiment of the invention there are provided methods and apparatus for a white light emitting LED lamp, an apparatus comprising an LED operative to emit blue light; a luminescent layer positioned to convert a part of the blue light into light having a longer wavelength; and a light transmitting element comprising a dye positioned to absorb a part of the blue light emitted by the LED.

In accordance with another embodiment of the invention there are provided methods and apparatus for a white light emitting LED lamp, an apparatus comprising: an LED configured to emit blue light; a luminescent layer configured to receive the blue light and convert a part of the blue light into light having a longer wavelength; and a dye configured to absorb a part of the blue light emitted by the LED.

In accordance with yet another embodiment of the invention there are provided methods and apparatus for a white light emitting LED lamp, an apparatus comprising an LED configured to emit blue light; a luminescent layer for receiving the blue light and converting a part of the blue light into light having a longer wavelength; and a light reflecting layer positioned to selectively reflect a part of the blue light emitted by the LED to the luminescent layer.

The inventors have realized that, if a certain thickness of luminescent material is given then providing an appropriate dye for absorbing a part of the blue light in a light emitting LED lamp having an LED emitting blue light and a luminescent layer for converting a part of the blue light into light having a longer wavelength more effectively and efficiently lowers the color temperature than the teachings of the prior art.

In comparison to the prior art, the result is an LED-powered white light lamp with a higher efficiency than using more luminescent material or using luminescent material converting the light into light having still a greater wavelength. An increase of the luminescent material would absorb more light which would overcompensate the further conversion from blue light into light having a longer wavelength. Using luminescent material which shifts the light to light having longer wavelength would cause a significant part of light intensity outside the sensitive range of the human eye. This light would be lost.

### BRIEF DESCRIPTION OF THE DRAWING FIGURES

These and other objects, features and advantages of the invention will be apparent from a consideration of the Detailed Description of the Invention with the drawing Figures, in which:

FIG. 1 is a graph showing a CIE chromaticity diagram;

FIG. 2 shows schematically an LED lamp according to the invention comprising an LED chip and a lens with yellow dye;

FIG. 3 is a graph showing a spectrum of the LED chip used in the lamp of FIG. 1;

FIG. 4 is a graph showing the standardized sensitivity graph of the human eye (Y(λ));

FIG. 5 is a graph showing the spectrum of FIG. 3 versus the standardized sensitivity of the human eye;

FIG. 6 is a graph showing the measurement points of the absorption of the yellow dye used in the lens of FIG. 1;

FIG. 7 is a graph showing the spectrum of the light of the LED chip of FIG. 1 before and after passing the lens containing the yellow dye, and the absorption spectrum of the yellow dye;

FIG. 8 is a graph showing the number of the blue photons and the yellow photons and dependency of the luminescent layer and the yellow dye;

FIG. 9 is a graph showing the luminous flux versus the correlated color temperature.

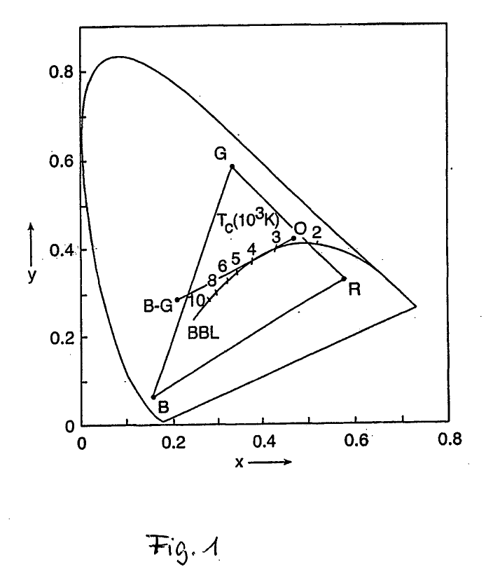

### DETAILED DESCRIPTION OF THE INVENTION

The invention relates to the discovery that a lamp employing a white light LED chip emitting blue and yellow light can achieve white light at higher efficiency with substantially uncompromised color rendering by using a dye for absorbing a part of the blue light.

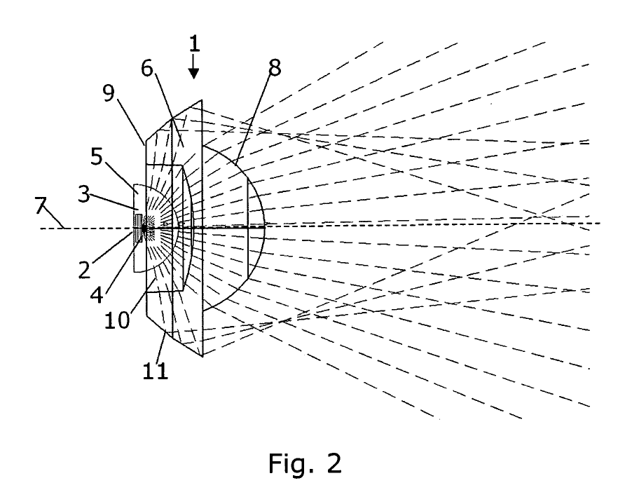

With reference to FIG. 2, a lamp 1 according to the invention comprises an LED chip 2 containing an embedded light emitting diode (LED). A luminescent coating 4 and a transparent dome 5 overlie LED chip 2 in the manner described below, forming an LED assembly 3.

The dome 5 is in the form of a hemisphere into which the LED chip 2 with coating 4 is embedded.

A lens 6 is arranged in front of and partially containing the LED assembly 3 in the manner described below.

The lens 6 is a body having a rotational symmetry around an optical axis 7. The lens 6 comprises an aspherical front part 8 being formed on a flange 9. The flange 9 comprises on the rear side a cavity 10 for taking up a part of the dome 5. Light rays emitted by the LED chip 2 enter the lens 6 in the range of the cavity 10, where a part of the light rays is directed to the aspherical front part 8 of lens 6 while the other part of the light rays is directed to a circumferential surface 11 of the flange 9. The circumferential aspherical surface 11 is tilted relative to the light rays in such a way that the light rays are totally reflected to the front side of the flange 9. As can be seen from FIG. 2 both bundles of light rays, that is those light rays passing through the spherical front part 8 and those light rays reflected by the circumferential surface 11, are superimposed at the front of the lamp 1.

According to the invention the lens 6 includes a yellow dye, i.e. a dye which is absorbing a part of the blue light emitted by the LED 3.

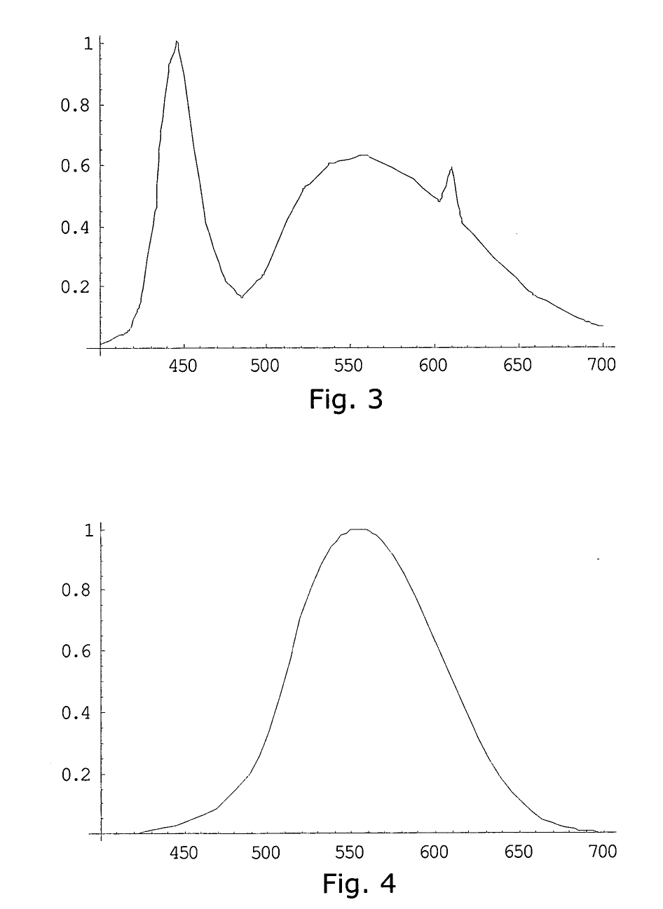

In the illustrative embodiment, LED assembly 3 is a white light LUXEON® III star of the type LXHL-LW3C available by Lumileds Lighting U.S. LLC, San Jose, Calif., U.S.A. This LED assembly comprises a lambertian light source having a spectrum as shown in FIG. 3. The diagram of FIG. 3 shows a strong blue peak at about 450 nm and a broad yellow peak in the range of about 530 nm to 600 nm. The temperature color of this white light is about 5500 K. It will be understood by the reader that any other LED having spectral characteristics that can be improved by the present invention can alternatively be used. Many such LEDs will now be apparent.

While exemplary components, elements, structures, materials and configurations are shown and described herein, they are not limiting. Any components, elements, structures, materials and configurations which perform the functions of the described invention may be used, with various alternate embodiments being described herein below.

FIG. 4 shows the function Y(λ) of the standardized sensitivity of the human eye.

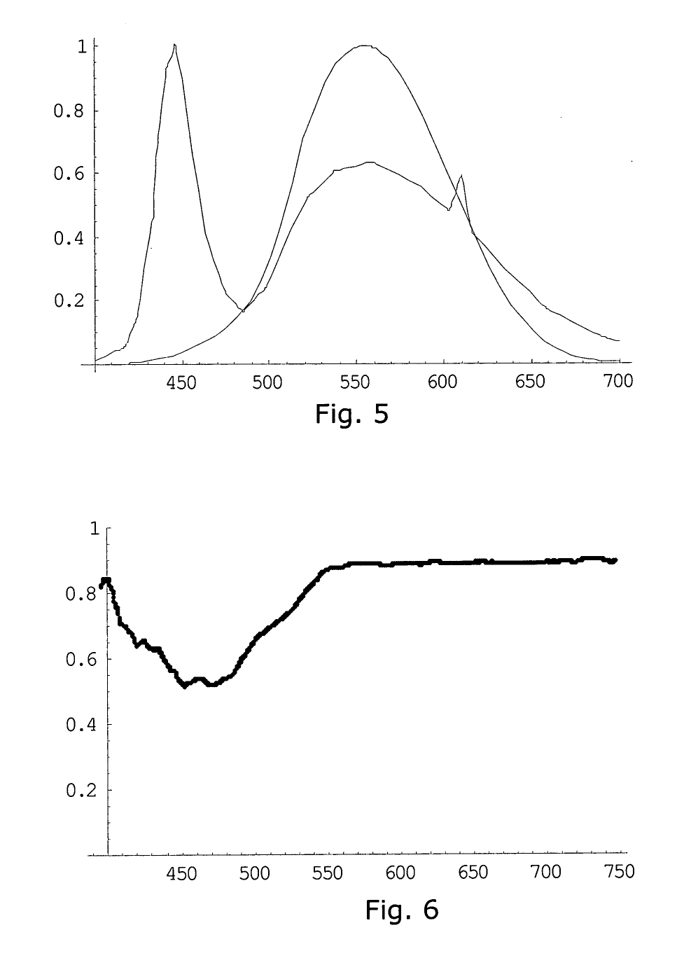

In FIG. 5 the absorption spectrum of the standardized sensitivity of the human eye Y(λ) is superimposed on the emission spectrum of the LED 3. As it can be seen in FIG. 5 the range of high sensitivity approximately coincides with the emission peak.

To produce a warmer light more of the blue light should be converted into yellow light. This would be very efficient, as the yellow light is detected by the human eye with a high sensitivity. This can be achieved principally by a thicker luminescent layer. However, as it is realized already in the art an increased luminescent thickness can decrease the whole system efficiency (see e.g. WO 01/89001 A2). Hence, in the prior art it was tried to circumvent this restriction by applying a mixture of different luminescent materials, where at least one luminescent material is provided emitting light having a greater wavelength than yellow light, e.g. red light, for decreasing the color temperature. However, as can be seen in FIG. 5, additional red light would cover the range with low sensitivity of the human eye, thus the resulting light would have a reduced luminous flux. The luminous flux is the radiant flux weighted by Y(λ). Thus, the overall efficiency of the light would be reduced.

To overcome these problems the lamp according to the invention comprises a yellow dye in lens 6 for absorbing a part of the blue light emitted by the LED 3. FIG. 6 shows a transmittance of light through a plastic plate comprising the dye of the present invention in relation to the wavelength λ. From FIG. 6 it can be seen that in the range of 450 nm to 480 nm a significant part of the light is absorbed. In the range of 530 nm and more the transmittance amounts to about 0.9 wherein 1 corresponds to the total transmittance. One exemplary dye is of the type 12896-GR and is available from GRAFE COLOR BATCH GmbH, Blankenhain, Germany. It will be understood that any dye having similar characteristics to and/or providing similar results to those described herein can alternatively be used. Many such dyes will now be apparent to the reader. A transmittance of 0.9 corresponds to a loss of light of about 0.1 which is mostly caused by the reflection of the two surfaces of the plastic plate according to Fresnel's law. Thus in this range nearly no light is absorbed by the dye. This means that blue light is absorbed by this dye whereas yellow and red light can pass through the dye with hardly any absorption.

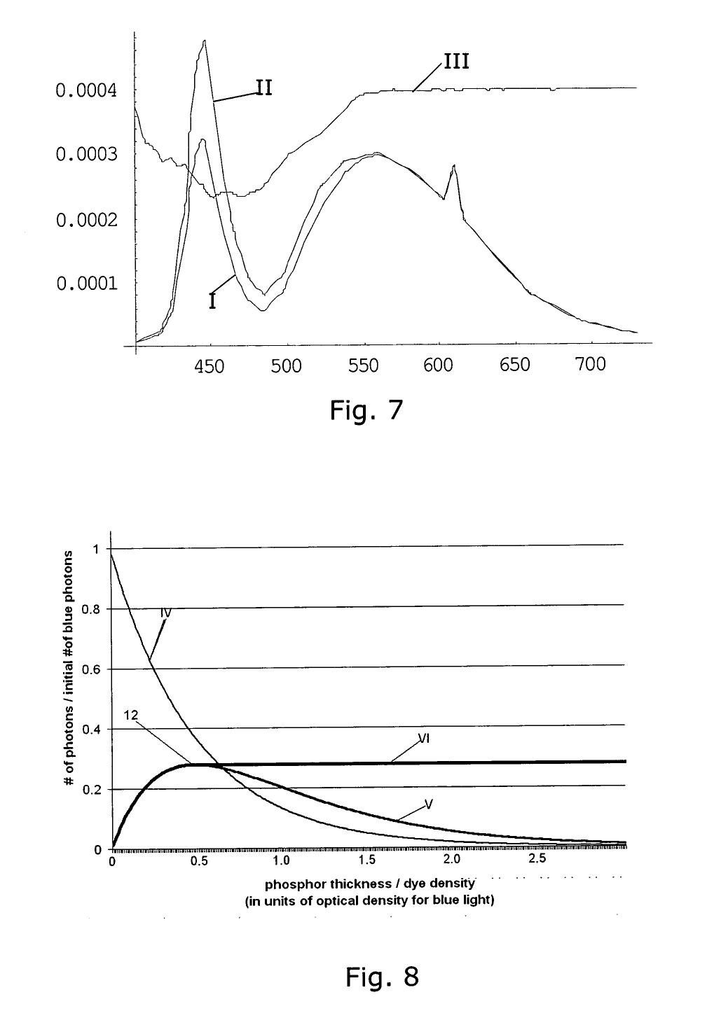

Using such a dye in combination with a blue light LED and a luminescent coating transmitting a part of the blue light into yellow light results in a spectrum with reduced intensity in the blue range (<480 nm) and maintaining the intensity in the yellow range (>530 nm) nearly unchanged. In FIG. 7 the spectrum I of the lamp according to the invention with the yellow dye is shown in comparison with the spectrum II of the same lamp without the yellow dye. In addition, the graph III of the transmission of the yellow dye is qualitatively depicted in FIG. 7.

FIG. 8 shows a simulation of the number of blue and yellow photons in relation to the thickness of the luminescent material and the density of the yellow dye. The curve IV shows the decrease of the number of blue photons with the increasing thickness of the luminescent coating and the increasing dye density. The thicker the luminescent coating is or the higher the density of the yellow dye is, the smaller is the number of blue photons emitted by the lamp. The curve V shows the number of the yellow photons by using only the luminescent coating without the yellow dye. As it can be seen there is a maximum at about 0.6 to 0.8 units of optical density for blue light. From this maximum in the direction to a higher thickness of the luminescent layer the curve is falling which means that the number of yellow photons is decreased by a further increase of the luminescent coating. The reason therefor is that the luminescent material does not only convert blue light into yellow light but also absorbs and reflects a certain proportion of blue and yellow light. So if the luminescent coating becomes too thick only a small proportion of the light can pass through the coating.

The maximum of the curve V corresponds about to the maximum overall luminous flux weighted by Y(λ), as the yellow-red-light has the most effect on this luminous flux. The region of the maximum of the curve V corresponds to the point in which a further increase of the thickness of the luminescent coating decreases the number of yellow photons or reduces the luminous flux of the converted light correspondingly. The reduced luminous flux 12 lowers the overall efficiency of the lamp.

According to the invention the yellow dye is provided in the optical path of the emitted light instead of further increasing the luminescent coating above the maximum 12. In other words, the LED assembly 3 comprises the LED chip 2 and the luminescent coating 4 with a thickness which corresponds to the thickness at the maximum 12 and in addition, the yellow dye in lens 6 is provided. This results in the curve VI, for the number of yellow photons in dependency of the phosphor thickness and the dye density. As can be seen from FIG. 8, the number of yellow photons is constant after it has once reached the maximum at 12, even if the density of the yellow dye is rather high. By the addition of the yellow dye only the number of the blue photons is decreased by which a reduction of the color temperature is achieved. The luminous flux is only decreased by a reduction of the number of blue photons but not by a reduction of the number of yellow photons. As the human eye is most sensitive in the range of yellow light the luminous flux weighted by V(λ) is not significantly reduced.

With the lamp according to the embodiment of the present invention the original color temperature of 5600 K of the LED chip is reduced to a color temperature of 4400 K without having a negative effect on the CRI. The total radiant flux is reduced by 12.3%, wherein the luminous flux is reduced by just 4.8%.

The lamp according to the invention keeps the thickness of the luminescent coating thin due to the use of the yellow dye which improves the usability of the lamp for optical design purposes, because the average luminescence of the light emitting surface is high and its edges are well defined.

A further advantage of the lamp according to the invention lies in the fact that a reduced proportion of blue light reduces glaring. This is particularly advantageous for being used as a headlamp for an automobile.

Furthermore, light having a reduced proportion of blue light is scattered by fog and smoke to a lesser extent than is light with a higher proportion of blue light. A flashlight provided with the lamp according to the invention is very advantageous for fire fighters.

In the embodiment as described above and shown in FIG. 2 a yellow dye is provided in the lens. In other embodiments, the yellow dye can be provided in the dome 5 or in the luminescent coating 4. For the invention it is important that the optical path of at least a part the light emitted by the LED passes through the yellow dye. It is preferred to separate the luminescent coating from the yellow dye, as in a mixture of the yellow dye and the luminescent coating the yellow dye would absorb a certain part of the blue light which is not anymore available to be converted into light with a longer wavelength.

According to a further embodiment of the invention a partially reflecting layer is provided which reflects only a proportion of the blue light. This layer is preferably provided on the surface of the dome 5. It is also possible to place this layer on one or both surfaces of the lens 6. This layer reflects a proportion of the blue light backwards to the luminescent coating 4 where the reflected blue light can excite the luminescent coating for emitting further yellow light. Thus, the overall luminous flux is increased by using such a partially reflecting layer instead of or in addition to the yellow dye.

A lamp according to the invention can also comprise any combination of the above described embodiments, such as when the yellow dye is provided in the luminescent coating and simultaneously in front of the luminescent coating, or when the yellow dye is provided in front of the luminescent coating and/or in the luminescent coating and a partially reflecting coating is provided.

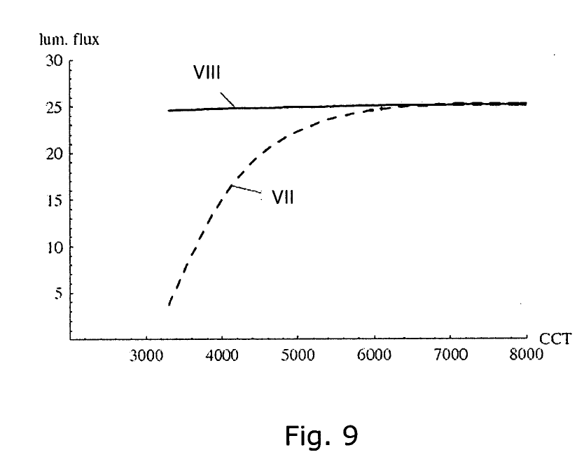

FIG. 9 shows in a diagram a theoretical simulation of the behavior of the luminous flux in arbitrary units in dependence of the correlated color temperature (CCT) for an ordinary lamp comprising an LED chip and a luminescent coating (line VII) and for a lamp according to the invention comprising an LED chip, a luminescent coating and a dye (line VIII). As it can be seen from FIG. 9 the luminous flux is significantly reduced if only the thickness of the luminescent coating is increased for lowering the correlated color temperature. On the other hand the luminous flux of a lamp according to the invention is reduced only by a very small amount when the correlated color temperature is lowered by adding more dye.

As mentioned above, the luminous flux is reduced by 4.8% for the lamp according to the embodiment of FIG. 2, when the original color temperature of 5600 K is reduced to a color temperature of 4400 K. This reduction of the luminous flux is greater than the reduction of the luminous flux as shown in FIG. 9, because the above mentioned commercially available yellow dye is used there having a gradual increase in transmittance between 480 nm and 530 nm. The reduction of the luminescent flux according to the theoretical simulations as shown in FIG. 9 is much smaller, because these theoretical simulations are based on a dye with a sudden increase in transmission at 480 nm.

The preferred embodiments have been set forth herein for the purpose of illustration. However, this description should not be deemed to be a limitation on the scope of the invention. Accordingly, various modifications, adaptations, improvements and alternatives may occur to one skilled in the art without departing from the spirit and scope of the claimed inventive concept.

What is claimed is:

1. A white light emitting LED lamp, comprising
an LED operative to emit blue light;
a luminescent layer positioned to convert a part of the blue light into light having a longer wavelength; and
a light transmitting element including a dye positioned to absorb a part of the blue light emitted by the LED.

2. The white light emitting LED lamp of claim 1, wherein the luminescent layer has a thickness corresponding to about the thickness at which the maximum luminous flux weighted by Y(λ) is achieved.

3. The white light emitting LED lamp of claim 1, wherein the light transmitting element comprises an optical lens.

4. The white light emitting LED lamp of claim 1, wherein the light transmitting element is selected from the group comprising a light transmitting glass, a plastic plate, and a film.

5. The white light emitting LED lamp of claim 1, wherein the dye absorbs at least a proportion of light having a wavelength smaller than 480 nm.

6. The white light emitting LED lamp of claim 5, wherein the dye does not significantly absorb light having a wavelength greater than 530 nm.

7. A white light emitting LED lamp, comprising
an LED configured to emit blue light,
a luminescent layer configured to receive the blue light and convert a part of the blue light into light having a longer wavelength; and
a dye configured to absorb a part of the blue light emitted by the LED.

8. The white light emitting LED lamp of claim 7, wherein the luminescent layer has a thickness corresponding to about the thickness at which the maximum luminous flux weighted by Y(λ) is achieved.

9. The white light emitting LED lamp of claim 7, further comprising an optical lens containing the dye.

10. The white light emitting LED lamp of claim 7, further comprising a container for the dye selected from the group comprising a light transmitting glass, a plastic plate, and a film.

11. The white light emitting LED lamp of claim 7, wherein the dye absorbs at least a portion of light having a wavelength smaller than 480 nm.

12. The white light emitting LED lamp of claim 11, wherein the dye does not significantly absorb light having a wavelength greater than 530 nm.

13. A white light emitting LED lamp, comprising
an LED configured to emit blue light;
a luminescent layer for receiving the blue light and converting a part of the blue light into light having a longer wavelength; and
a light reflecting layer positioned to selectively reflect a part of the blue light emitted by the LED to the luminescent layer.

14. The white light emitting LED lamp of claim 13, wherein the luminescent layer has a thickness corresponding to about the thickness at which the maximum luminous flux weighted by Y(λ) is achieved.

15. A method for generating white light using an LED, comprising
providing an LED operative to emit blue light;
positioning a luminescent layer to convert a part of the blue light into light having a longer wavelength; and
positioning a light transmitting element including a dye to absorb a part of the blue light emitted by the LED.

16. A method to generate white light, comprising
operating an LED to emit blue light,
converting, using a luminescent layer, a part of the blue light into light having a longer wavelength; and
absorbing, using a dye, a part of the blue light emitted by the LED;
whereby the blue light emitted by the LED is altered to a white light.

17. A method to generate white light, comprising
providing an LED configured to emit blue light;
receiving the blue light a luminescent layer for converting a part of the blue light into light having a longer wavelength; and
selectively reflecting a part of the blue light emitted by the LED to the luminescent layer.
